(19) United States
(12) Patent Application Publication
(10) Pub. No.: US 2007/0072995 A1
(43) Pub. Date: Mar. 29, 2007

(54) Thermoplastic resin composition with improved properties

(76) Inventors: Tae Gon Kang, Suwon-si (KR); Sung Sig Min, Seoul (KR); Jong Cheol Lim, Annyang-si (KR); Kyung Hoon Seo, Seoul (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/522,231

(22) Filed: Sep. 15, 2006

Related U.S. Application Data
(63) Continuation-in-part of application No. PCT/KR05/00696, filed on Mar. 11, 2005.

(30) Foreign Application Priority Data
Mar. 15, 2004 (KR) 10-2004-0017366

(51) Int. Cl. C08L 53/00; C08L 69/00; H01L 21/00; B32B 27/00

(52) U.S. Cl. 525/92 E; 525/461; 438/106

(57) ABSTRACT

A thermoplastic composition and its use as a molded article and as housing or a part of electronic device are disclosed. The thermoplastic composition includes one or more of a polycarbonate resin, an ethylene-alkyl (meth)acrylate copolymer resin, a rubber modified vinyl graft copolymer resin, and a vinyl copolymer. The thermoplastic compositions described herein have one or more of improved impact strength, flowability, and thermal stability.

### CROSS-REFERENCE TO RELATED APPLICATIONS

This application is a continuation-in-part application under 35 U.S.C. § 365 (c) claiming the benefit of the filing date of PCT Application No. PCT/KR2005/000696 designating the United States, filed Mar. 11, 2005. The PCT Application was published in English as WO 2006/001570 A1 on Jan. 5, 2006, and claims the benefit of the earlier filing date of Korean Patent Application No. 10-2004-0017366, filed Mar. 15, 2004. The contents of the PCT Application including its international publication and Korean Patent Application No. 10-2004-0017366 are incorporated herein by reference in their entirety.

### BACKGROUND

1. Field

The invention relates to polymer compositions, particularly those comprising a polycarbonate resin and an ethylene-alkyl (meth)acrylate copolymer resin.

2. Description of the Related Technology

Polycarbonate resins have been widely used as an engineering plastic material. Particularly, the polycarbonate resins are extensively used in housings and other parts of portable electronic devices including mobile phones. Certain physical or mechanical properties of these polycarbonate-based articles may deteriorate as these articles are used frequently. Therefore, such polycarbonate resins often require good impact strength. Additionally, polycarbonate based compositions may require good flowability and thermal stability as the compositions are applied to heat emitting products, such as automobile parts, computer housings and office supplies.

### SUMMARY

Described herein are polymer compositions. In some embodiments, the polymer composition comprises a polycarbonate resin and an ethylene-alkyl (meth)acrylate copolymer resin. In some embodiments, the polymer composition comprises about 45 to about 95 parts by weight of the polycarbonate resin and about 0.1 to about 50 parts by weight of the ethylene-alkyl (meth)acrylate copolymer resin. In some embodiments, the polycarbonate resin and the ethylene-alkyl (meth)acrylate copolymer resin total 100 parts by weight.

In some particular embodiments, the polymer composition comprises about 50 to about 90 parts by weight of the polycarbonate resin. In another composition, the polymer composition comprises about 50 to about 85 parts by weight of the polycarbonate composition.

In one embodiments, the ethylene-alkyl (meth)acrylate copolymer resin comprises a polymer represented by Formula (I):

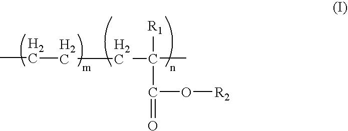

In formula (I), R₁ is hydrogen or methyl, R₂ is hydrogen or C₁-C₁₂ alkyl, and the ratio of m to n ranges from about 300:1 to about 10:90. In some embodiments, the polymer represented by Formula (I) comprises one or more selected from the group consisting of a random polymer, a block polymer, and a multiblock polymer. In some embodiments, R₂ is selected from the group consisting of hydrogen, methyl, ethyl, propyl, isopropyl, butyl, sec-butyl, t-butyl, isobutyl, isoamyl and t-amyl.

In some embodiments, the ethylene-alkyl (methyl) acrylate copolymer is a copolymer of ethylene and at least one monomer selected from the group consisting of acrylate, methyl acrylate, ethyl acrylate, propyl acrylate, isopropyl acrylate, butyl acrylate, sec-butyl acrylate, t-butyl acrylate, isobutyl acrylate, isoamyl acrylate, and t-amyl acrylate, methacrylate. methyl methacrylate, ethyl methacrylate, propyl methacrylate, isopropyl methacrylate, butylmethacrylate, sec-butyl methacrylate, t-butylmethacrylate, isobutyl methacrylate, isoamyl methacrylate, and t-amyl methacrylate.

According to some embodiments, the polymer composition has one or more of enhanced physical properties including impact strength, flowability, and thermal stability. In one embodiments, the polymer composition has impact strength of greater than or equal to about 35 kgf·cm/cm, when a specimen of the composition is tested according to the standard ASTM D256 (¼″ notched) at 23° C. In another embodiment, the polymer composition has impact strength of greater than or equal to about 38 kgf·cm/cm, when a specimen of the composition is tested according to the standard ASTM D256 (¼″ notched) at 23° C. In another embodiment, the polymer composition has a Heat Distortion Temperature of greater than or equal to about 120° C., when a specimen of the thermoplastic composition is tested in accordance with ASTM D648 under a 18.6 kgf load. In another embodiment, the polymer composition has a Heat Distortion Temperature of greater than or equal to about 127° C., when a specimen of the thermoplastic composition is tested in accordance with ASTM D648 under a 18.6 kgf load.

In some embodiments, the polymer composition is in the form of a molded article. In certain embodiments, the polymer composition further comprises one or more of a rubber modified vinyl graft copolymer resin and a vinyl copolymer. In some of these embodiments, the vinyl copolymer resin is present in addition to a second vinyl copolymer of the rubber modified vinyl graft copolymer resin. For example, the vinyl copolymer is added in addition to excess second vinyl copolymer of the rubber modified vinyl graft copolymer.

In some embodiments, the polymer composition comprises about 0 to about 50 parts by weight of the rubber modified vinyl graft copolymer resin and about 0 to about 50 parts by weight of the vinyl copolymer.

Certain embodiments comprising one or more of the rubber modified vinyl graft copolymer resin and the vinyl copolymer have one or more improved physical properties selected from impact strength, flowability, and thermal stability. In some embodiments, a polymer composition comprising a rubber modified vinyl graft copolymer resin and a vinyl copolymer has impact strength of greater than or equal to about 52 kgf·cm/cm, when a specimen of the composition is tested according to the standard ASTM D256 (¼″ notched) at 23° C. In another embodiment, the polymer composition has impact strength of greater than or equal to about 55 kgf·cm/cm, when a specimen of the composition is tested according to the standard ASTM D256 (¼″ notched) at 23° C. In another embodiment, the polymer composition has impact strength of greater than or equal to about 61 kgf·cm/cm, when a specimen of the composition is tested according to the standard ASTM D256 (¼″ notched) at 23° C.

In some embodiments, the polymer composition has a Heat Distortion Temperature of greater than or equal to about 112° C., when a specimen of the thermoplastic composition is tested in accordance with ASTM D648 under a 18.6 kgf load. In some embodiments, the polymer composition has a Heat Distortion Temperature of greater than or equal to about 117° C., when a specimen of the thermoplastic composition is tested in accordance with ASTM D648 under a 18.6 kgf load.

In some embodiments, the polymer composition has a melt flow index of greater than or equal to about 5 g/10 min, when a specimen of the thermoplastic composition is tested according to the standard ASTM D1238 at 250° C. and a 2.16 kg load.

In some embodiments, the polymer composition has a melt flow index of greater than or equal to about 8 g/10 min, when a specimen of the thermoplastic composition is tested according to the standard ASTM D1238 at 250° C. and a 2.16 kg load. In some embodiments, the polymer composition has a melt flow index of greater than or equal to about 10.6 g/10 min, when a specimen of the thermoplastic composition is tested according to the standard ASTM D1238 at 250° C. and a 2.16 kg load.

In some embodiments, a method of making a plastic structure comprises providing one or more of the polymer compositions as herein described and molding the polymer composition into a shape. In another embodiment, a method of making an electronic device comprises providing an electronic circuit and providing a housing substantially enclosing the electronic circuit, the housing comprising a portion, which comprises the polymer composition as herein described.

In some embodiments, an electronic device comprises a housing, wherein the housing comprises a portion comprising one or more of the polymer compositions as herein described. In some embodiments, the polymer compositions as herein described may be formed as a shaped article.

### DETAILED DESCRIPTION OF EMBODIMENTS

As noted above, one aspect of this invention relates to a polymer composition. According to various embodiments, the polymer composition contain a polycarbonate resin and a ethylene-alkyl (meth)acrylate copolymer resin. In some embodiments, the alkyl (meth) acrylate copolymer resin has the following formula:

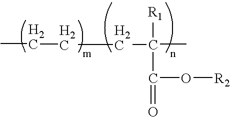

In the formula, R₁ is hydrogen or methyl, R₂ is hydrogen or C₁-C₁₂ alkyl, and the ratio of m to n ranges from about 300:1 to about 10:90.

Additionally, some embodiments of the polymer composition also contain a rubber modified vinyl graft resin. In some embodiments, the thermoplastic composition may also comprise a vinyl copolymer.

Articles comprising the thermoplastic compositions of the embodiments show enhanced physical or mechanical properties as compared to other compositions less one or more components. The compositions of the embodiments also demonstrate one or more of improved impact strength, melt flow index, or heat distortion temperatures compared to compositions less one or more components. Such compositions may also maintain a good balance of other physical and mechanical properties.

The components of the thermoplastic composition are further described here.

Polycarbonate Resin

The polycarbonate resin used in some embodiments includes a polycarbonate compound or a mixture of two or more polycarbonate compounds. The resulting polymer of the polycarbonate compound or mixture of two or more polycarbonate compounds is also referred to as a polycarbonate resin. The polycarbonate compounds include homopolymers or copolymers containing a repeating ester group. For example, the polycarbonate compounds include linear or branched polycarbonate compounds, and further include polyester carbonate copolymers, silicone-polycarbonate copolymers, and other copolymers containing carbonate. The skilled artisan will appreciate additional examples of the polycarbonate compounds. Additionally, a homopolymer of a polycarbonate resin, a copolymer of polycarbonate resin, or mixtures thereof may be used according to some embodiments.

Typically, one or more polycarbonate compounds may be obtained from a reaction of one or more diphenols with a carbonate precursor or phosgene in the presence of a molecular weight controlling agent and usually in the presence of a catalyst. A reaction involving two diphenols may result in a copolymeric polycarbonate compound. Typical examples of the diphenol used include hydroquinone, resorcinol, 4,4′-dihydroxydiphenyl, bis(4-hydroxyphenyl)methane, bis {(4-hydroxy-3,5-dimethyl)phenyl}methane, 1,1-bis(4-hydroxyphenyl)ethane, 1,1-bis(4-hydroxyphenyl)-1-phenylethane, 2,2-bis(4-hydroxyphenyl)propane (generally called bisphenol A), 2,2-bis{(4-hydroxy-3-methyl)phenyl}propane, 2,2-bis-(3-chloro-4-hydroxyphenyl)-propane, 2,2-bis {(4-hydroxy-3,5-dimethyl)phenyl}propane, 2,2-bis {(3,5-dibromo-4-hydroxy)phenyl}propane, 2,2-bis {((3-isopropyl-4-hydroxy)phenyl}propane, 2,2-bis {(4-hydroxy-3-phenyl)phenyl}propane, 2,2-bis(4-hydroxyphenyl)butane, 2,2-bis(4-hydroxyphenyl)-3-methylbutane, 2,2-bis(4-hydroxyphenyl)-3,3-dimethylbutane, 2,4-bis(4-hydroxyphenyl)-2-methylbutane, 2,2-bis(4-hydroxyphenyl)pentane, 2,2-bis(4-hydroxyphenyl)-4-methylpentane, 1,1-bis(4-hydroxyphenyl)cyclohexane, 1,1-bis(4-hydroxyphenyl)-4-isopropylcyclohexane, 2,2-bis-(3,5-dichloro-4-hydroxyphenyl)-propane, 2,2-bis-(3,5-dibromo-4-hydroxyphenyl)-propane 1,1-bis(4-hydroxyphenyl)-3,3,5-trimethylcyclohexane, 9,9-bis(4-hydroxyphenyl)fluorene, 9,9-bis {(4-hydroxy-3-methyl)phenyl}fluorene, α,α′-bis(4-hydroxyphenyl)-o-diisopropylbenzene, α,α′-bis(4-hydroxyphenyl)-m-diisopropylbenzene, α,α′-bis(4-hydroxyphenyl)-p-diisopropylbenzene, 1,3-bis(4-hydroxyphenyl)-5,7-dimethyladamantane, 4,4′-dihydroxydiphenyl sulfone, 4,4′-dihydroxydiphenyl sulfoxide, 4,4′-dihydroxydiphenyl sulfide, 4,4′-dihydroxydiphenyl ketone, 4,4′-dihydroxydiphenyl ether and 4,4′-dihydroxydiphenyl ester. Typically, the carbonate precursor is a carbonyl halide, carbonate ester, haloformate or the like. Specific examples of the carbonate precursor include phosgene, diphenyl carbonates and dihaloformates of diphenols.

In some embodiments, the polycarbonate resin is prepared by reacting a diphenol represented by the following formula (I) with a phosgene, a halogen formate or a carboxylic acid diester:

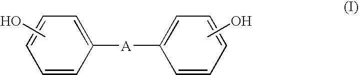

In formula (I), A may be a single bond, a C₁₋₅ alkylene group, a C₁₋₅ alkylidene group, a C₅₋₆ cycloalkylidene group, S or SO₂.

In one embodiment, the polycarbonate compound includes 2,2-bis-(4-hydroxyphenyl)-propane polycarbonate compound, which is a linear polycarbonate compound. In another embodiment, a branched polycarbonate compound can be obtained by reacting a polyfunctional aromatic compound such as trimelitic anhydride and trimelitic acid with dihydric phenol and a carbonate precursor. In another embodiment, another polycarbonate compound can be obtained by reacting a difunctional carboxylic acid with dihydric phenol and a carbonate precursor. In another embodiment, some portion of the polycarbonate resin may be replaced with an aromatic polyester-carbonate resin. In the foregoing embodiment, the aromatic polyester-carbonate resin may be obtained by polymerization of the polycarbonate in the presence of an ester precursor, such as difunctional carboxylic acid.

In some embodiments, a polycarbonate resin having a weight average molecular weight (M_{w}) of about 10,000 to about 200,000 is used. In other embodiments, a polycarbonate resin having M_{w} of about 15,000 to about 80,000 is used.

In some embodiments, the polycarbonates resin may be substituted in any manner. In some embodiments, the polycarbonate resin is branched. In some embodiments, the polycarbonate resin may be branched by incorporation of about 0.05 to about 2 mol % of tri- or higher functional compounds, based to total quantity of diphenols used. For example, compounds with three or more phenolic groups may be used in forming the polycarbonate resin.

In some embodiments, the thermoplastic resin composition comprises about 45 to about 95 parts by weight of a polycarbonate resin, which includes, for example, approximately 50, 55, 60, 65, 70, 75, 80, 85, 90 or 95 parts by weight. In certain embodiments, the composition may contain the polycarbonate resin in an amount within a range formed by the two of the foregoing approximate parts by weigh. In certain embodiments, the thermoplastic composition comprises an amount of a polycarbonate resin ranged between two of the foregoing values. In other embodiments, the thermoplastic composition comprises about 50 to about 90 parts by weight of the polycarbonate resin. In a few embodiments, the thermoplastic composition comprises up to about 99.5 parts by weight of the polycarbonate resin. Here, the unit “parts by weight” refers to a relative weight of each component given that the total weight of the one or more of the polycarbonate resin, the ethylene/alkyl (meth)acrylate copolymer, the rubber modified vinyl-graft copolymer, and the vinyl copolymer is 100 parts by weight.

Ethylene-Alkyl (Meth)Acrylate Copolymer Resin

In particular embodiments, the ethylene-alkyl (meth)acrylate copolymer is a copolymer of an olefin monomer and an alkyl (meth)acrylate monomer. Olefins or olefin monomers, also called alkenes, are unsaturated hydrocarbons whose molecules contain one or more pairs of carbon atoms linked together by a double bond. Examples of polyolefins are polyethylene, polypropylene, polyisopropylene, polybutylene, etc. In some embodiments, ethylene is used as an olefin monomer. In other embodiments, mixtures of the olefins may be used as monomers.

The alkyl (meth)acrylate monomer used in these embodiments may be a methacrylate monomer or an acrylate monomer. In some embodiments, these monomers may be substituted in any fashion. Examples include, but are not limited to, methyl acrylate, ethyl acrylate, propyl acrylate, isopropyl acrylate, butyl acrylate, sec-butyl acrylate, t-butyl acrylate, isobutyl acrylate, isoamyl acrylate, and t-amyl acrylate. Other embodiments may use the monomers methyl methacrylate, ethyl methacrylate, propyl methacrylate, isopropyl methacrylate, butylmethacrylate, sec-butyl methacrylate, t-butylmethacrylate, isobutyl methacrylate, isoamyl methacrylate, and t-amyl methacrylate.

The olefin and alkyl (meth)acrylate monomers may be reacted together to form an olefin-alkyl (meth)acrylate copolymer resin. In some embodiments, ethylene monomers and alkyl (meth)acrylate monomers may be reacted together to form ethylene-alkyl (meth) acrylate monomers. The syntheses of copolymers of olefin and alkyl (meth)acrylate monomers is well known in the art. In some embodiments, the olefin-alkyl (meth)acrylate copolymer may be one selected from random, block, multi-block, graft copolymers, and mixtures thereof. In some embodiments, the olefin is about X to about Y weight percent, and the alkyl (meth)acrylate copolymer is about X to about Y weight percent.

In some embodiments, the ethylene-alkyl (meth)acrylate copolymer is represented by the following formula (II):

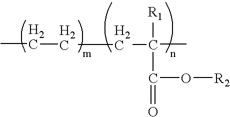

In the formula, R₁ is hydrogen or methyl. In some embodiments, R₂ is hydrogen or C₁-C₁₂ alkyl, including, but not limited to, methyl, ethyl, propyl, isopropyl, butyl, sec-butyl, t-butyl, isobutyl, isoamyl, or t-amyl. In some embodiments, the ratio of “m” to “n” ranges from about 300:1 to about 10:90.

In these embodiments, —CH₂—CH₂— (hereinafter “m monomer unit”) and CH₂—CR₁(COOR₂)— (hereinafter “n monomer unit”) may repeat in any fashion. In some embodiments, m monomer units are connected directly to other m monomer units. Alternatively, m monomer units can be adjacent to n monomer units. Thus, an ethylene-alkyl (meth)acrylate copolymer can, for example, includes units m-n-m-n-m-n, m-m-m-n-n-m-m-m, m-m-m-m-n-n-n-n, and so forth, in which for the sake of convenience the m and n monomer units are represented as “m” and “n” respectively. Thus, the combination of “m” and “n” monomer units can be in any arrangement in the ethylene-alkyl(meth)acrylate copolymer. In some embodiments, the ethylene-alkyl (meth)acrylate copolymer is one or more of a random, block, or multiblock polymer.

In some embodiments, the ethylene-alkyl (meth)acrylate copolymer will have a melt index of from about 0.1 to about 40 g per/10 minutes under conditions of 190° C. and 2.16 kgf, and more preferably a melt index of 1 to 10 g per 10 minutes under the same conditions.

In some embodiments, the thermoplastic resin composition comprises about 0.1 to about 20 parts by weight of a ethylene-alkyl (meth)acrylate copolymer resin, which includes, for example, approximately 0.5, 1, 1.5, 2, 2.5, 3, 3.5, 4, 4.5, 5, 5.5, 6, 6.5, 7, 7.5, 8, 8.5, 9, 9.5, 10, 10.5, 11, 11.5, 12, 12.5, 13, 13.5, 14, 14.5, 15, 15.5, 16, 16.5, 17, 17.5, 18, 18.5, 19, 19.5, or 20. In certain embodiments, the composition may contain the ethylene-alkyl (meth)acrylate copolymer resin in an amount within a range formed by the two of the foregoing approximate parts by weigh. In certain embodiments, the thermoplastic composition comprises an amount of a ethylene-alkyl (meth)acrylate copolymer resin ranged between two of the foregoing values. In other embodiments, the thermoplastic composition comprises about 10 to about 40 parts by weight of the ethylene-alkyl (meth)acrylate copolymer resin. Here, the unit “parts by weight” refers to a relative weight of each component given that the total weight of the one or more of the polycarbonate resin, the ethylene/alkyl (meth)acrylate copolymer, the rubber modified vinyl-graft copolymer, and the vinyl copolymer is 100 parts by weight.

Rubber Modified Vinyl Graft Copolymer

In some embodiments, an optional rubber modified vinyl graft copolymer comprises a copolymer grafted onto an olefinic polymer substrate. The copolymer which is grafted onto the substrate may be a polymer of one or more of a monovinylidene aromatic monomers such as styrenic compounds, and unsaturated copolymerizable monomers such as alkyl esters of (meth)acrylic acid, maleic anhydride, maleic anhydride derivatives such as N-substituted maleimides, and ethylenically unsaturated nitrile monomers (such as acrylonitrile compounds). Such a copolymer is grated onto an olefinic polymer substrate. In some embodiments, the polymer substrate is a rubber.

In some embodiments, the copolymer may be prepared by polymerizing a monomer mixture consisting of about 50 to about 95% by weight of one or more of styrene, α-methylstyrene, halogen- or alkyl-substituted styrene, C₁₋₈ methacrylic acid alkyl ester, or C₁₋₈ acrylic acid alkyl ester, and 5 to about 50% by weight of one or more of acrylonitrile, methacrylonitrile, C₁₋₈ methacrylic acid alkyl ester, C₁₋₈ acrylic acid alkyl ester, maleic acid anhydride, C₁₋₄ alkyl- or phenyl N-substituted maleimide or a mixture there. In some embodiments, the C₁₋₈ methacrylic acid alkyl ester or the C₁₋₈ acrylic alkyl ester is an ester of methacrylic acid or acrylic acid, respectively. In some embodiments, they are the acrylic acid esters of monohydric alcohols with about 1 to about 8 carbon atoms. The examples of the acid alkyl ester include methacrylic acid methyl ester, methacrylic acid ethyl ester, acrylic acid ethyl ester, acrylic acid methyl ester or methacrylic acid propyl ester.

The copolymer may be grafted onto the olefinic polymer substrate. In some embodiments, the above produced about 5 to about 95% by weight of copolymer is grafted onto about 5 to about 95% by weight of a rubber polymer selected from the group consisting of one or more of butadiene rubber, acryl rubber, ethylene-propylene rubber, styrene-butadiene rubber, acrylonitrile-butadiene rubber, isoprene rubber, copolymer of ethylene-propylene-diene (EPDM), or polyorganosiloxane-polyalkyl(meth)acrylate rubber complex. In some embodiments, the rubber has an average particle size of about 0.05 to about 4.0 μm. However, particle size may be varied in view of the impact strength and appearance of the overall resin.

In some embodiments, the rubber modified vinyl graft copolymer is a grafted-copolymers of styrene and acrylonitrile, and optionally (meth)acrylic acid alkyl ester, on one or more rubbers selected from butadiene rubber, acryl rubber, or styrene-butadiene rubber. In another embodiments, the rubber modified vinyl graft copolymer is a graft copolymer of one or more (meth)acrylic acid alkyl esters on one or more rubbers selected from butadiene rubber, acryl rubber, or styrene-butadiene rubber. In an embodiment, the rubber modified vinyl graft copolymer is an acrylonitrile-butadiene-styrene (ABS) resin.

In some embodiments, the rubber modified graft copolymer is prepared through a conventional polymerization process such as emulsion, suspension, solution, or bulk process. In some embodiments, the emulsion or bulk polymerization is preferred.

In some embodiments, the thermoplastic resin composition does not comprise the rubber modified vinyl grafted copolymer resin. In other embodiments, the thermoplastic composition comprises about 0.1 to about 50 parts by weight of the rubber modified vinyl grafted copolymer resin, which includes, for example, approximately 5, 10, 15, 20, 25, 30, 35, 40, 45, or 50 parts by weight. In certain embodiments, the composition may contain the rubber modified vinyl grafted copolymer resin in an amount within a range formed by the two of the foregoing approximate parts by weigh. In certain embodiments, the thermoplastic composition comprises an amount of a rubber modified vinyl grafted copolymer resin ranged between two of the foregoing values. In other embodiments, the thermoplastic composition comprises about 30 to about 70 parts by weight of the rubber modified vinyl graft copolymer resin. Here, the unit “parts by weight” refers to a relative weight of each component given that the total weight of the one or more of the polycarbonate resin, the ethylene/alkyl (meth)acrylate copolymer, the rubber modified vinyl-graft copolymer, and the vinyl copolymer is 100 parts by weight.

(D) Vinyl Copolymer

In some embodiments, the thermoplastic composition optionally comprises a vinyl copolymer. The vinyl copolymer may be a polymer of one or more of a monovinylidene aromatic monomers such as styrenic compounds, and unsaturated copolymerizable monomers such as alkyl esters of (meth)acrylic acid, maleic anhydride, maleic anhydride derivatives such as N-sustituted maleimides, and ethylenically unsaturated nitrile monomers (such as acrylonitrile compounds). In some embodiments, the vinyl copolymer is the same as the copolymer grafted onto the olefinic substrate of the rubber modified vinyl grafted copolymer. In other embodiments, the vinyl copolymer is different than the copolymer grafted onto the olefinic substrate of the rubber modified vinyl grafted copolymer.

In some embodiments, the vinyl copolymer may be prepared by polymerizing about 50 to about 95% by weight of one or more of styrene, α-methylstyrene, halogen- or alkyl-substituted styrene, C₁₋₈ methacrylic acid alkyl ester, or C₁₋₈ acrylic acid alkyl ester, and 5 to 50% by weight of one or more of acrylonitrile, methacrylonitrile, C₁₋₈ methacrylic acid alkyl ester, C₁₋₈ acrylic acid alkyl ester, maleic acid anhydride, or C₁₋₄ alkyl- or phenyl N-substituted maleimide. In some embodiments, the C₁₋₈ methacrylic acid alkyl ester or the C₁₋₈ acrylic alkyl ester is an ester of methacrylic acid or acrylic acid, respectively. In some embodiments, they are the acrylic acid esters of monohydric alcohols with about 1 to about 8 carbon atoms. Examples of the acid alkyl ester include methacrylic acid methyl ester, methacrylic acid ethyl ester, acrylic acid ethyl ester, acrylic acid methyl ester or methacrylic acid propyl ester. In some particular embodiments, a styrene compound comprises one or more of styrene, p-methylstyrene, vinyltoluene, 2,4-dimethylstyrene, or α-methylstyrene.

One example of a vinyl copolymer is a polymer of the monomers selected from styrene, acrylonitrile, and optionally a (meth)acrylic acid methyl ester. Another example of a vinyl copolymer is a polymer of monomer mixture of α-methyl styrene, acrylonitrile, and optionally a (meth)acrylic acid methyl ester. Yet another nonlimiting example of a vinyl copolymer is a polymer of a monomer mixture comprising styrene, α-methyl styrene acrylonitrile, and optionally a (meth)acrylic acid methyl ester.

In some embodiments, the vinyl copolymer is a by-product in the preparation of the rubber modified vinyl-grafted copolymer. Such by-products may be produced when a large quantity of monomers are grafted onto a small amount of rubber polymer (e.g., excessive copolymer or monomer units) or when a chain transfer agent is used in excess. However, the amount of the vinyl copolymer used, according to some embodiments, does not include the amount of by-product that may be produced during preparation of the rubber modified vinyl-grafted copolymer. In the foregoing embodiments, the vinyl copolymer may be prepared by emulsion, suspension, solution, or a bulk process. In the foregoing embodiments, the vinyl copolymer has a weight average molecular weight (M_{w}) of about 15,000 to about 200,000. In other embodiments, a weight average molecular weight (M_{w}) of about 20,000 to about 250,000

Another nonlimiting example of a vinyl copolymer is a polymer of one or more methacrylic acid methyl ester monomers and optionally acrylic acid methyl or ethyl ester monomers. In the foregoing embodiments, the vinyl copolymer may be prepared by a emulsion, suspension, solution or bulk process, and has a weight average molecular weight (M_{w}) of about 20,000 to about 250,000.

Another nonlimiting example of a vinyl copolymer is a copolymer of styrene and maleic acid anhydride. This copolymer may be prepared by a continuous bulk process and/or a solution process. In one embodiment, maleic acid anhydride is preferably used in the amount of about 5 to about 50% by weight. In some of the foregoing embodiments, the vinyl copolymer of styrene and maleic acid anhydride has a weight average molecular weight (M_{w}) of about 20,000 to about 200,000 and an intrinsic viscosity of about 0.3 to about 0.9 cm³/g.

In some embodiments, the thermoplastic resin composition does not comprise the vinyl copolymer. In other embodiments, the thermoplastic composition comprises about 0.1 to about 50 parts by weight of the vinyl copolymer, which includes, for example, approximately 5, 10, 15, 20, 25, 30, 35, 40, 45, or 50 parts by weight. In certain embodiments, the composition may contain the vinyl grafted resin in an amount within a range formed by the two of the foregoing approximate parts by weigh. In certain embodiments, the thermoplastic composition comprises an amount of a vinyl copolymer ranged between two of the foregoing values. In other embodiments, the thermoplastic composition comprises about 30 to about 70 parts by weight of the vinyl copolymer. Here, the unit “parts by weight” refers to a relative weight of each component given that the total weight of the one or more of the polycarbonate resin, the ethylene/alkyl (meth)acrylate copolymer, the rubber modified vinyl-graft copolymer, and the vinyl copolymer is 100 parts by weight.

Additional Components

The thermoplastic composition may additionally comprise one or more other additives such as organic fillers, like glass fiber, carbon fiber, talc, silica, mica, and alumina. The composite materials can contain one or more of an ultraviolet absorbing agent, a heat stabilizer, an antioxidant, a flame retardant, a lubricant, a colorant, such as a pigment or dye, in addition to the foregoing components. Additional components or additives may be added to provide additional properties or characteristics to the composite material or to modify existing properties of the composite material. One of ordinary skill in the art will appreciate that various additives may be added to the composite materials according to some embodiments.

In some embodiments, the thermoplastic composition may further contain one or more flame retardant including, but not limited to, a phosphoric acid ester such as a monomeric or oligomeric phosphoric acid ester, a phosphazene compound; a metal salt of aromatic sulfonamide, a metal salt of aromatic sulfonic acid and/or a metal salt of perfluoroalkane sulfonic acid.

In some embodiments, the one or more additives comprise about 0 to about 60 parts by weight, based on the total weight of the one or more of the polycarbonate resin, the ethylene/alkyl (meth)acrylate copolymer, the rubber modified vinyl-graft copolymer, and the vinyl copolymer equaling 100 parts by weight. In another embodiment, the one or more additives comprise about 0.5 to about 40 parts by weight.

Properties of the Thermoplastic Composition

An advantage of certain embodiments is to provide a thermoplastic resin composite material with improved physical and mechanical properties. Such properties include, but are not limited to, impact strength, flowability, and thermal stability.

Some embodiments described herein related to a thermoplastic resin comprising a polycarbonate resin and an ethylene-alkyl(meth)acrylate copolymer resin. Such compositions offer certain advantages over composition less one or more components. In some embodiments, a thermoplastic resin comprising a polycarbonate resin and an ethylene-alkyl(meth)acrylate copolymer resin has an impact strength of greater than or equal to about 35 kgf·cm/cm, when a specimen of the thermoplastic composition is tested according to the standard ASTM D256 (¼″ notched) at 23° C. In some embodiments, a thermoplastic resin comprising a polycarbonate resin and an ethylene-alkyl(meth)acrylate copolymer resin has an impact strength of greater than or equal to about 38 kgf·cm/cm, when a specimen of the thermoplastic composition is tested according to the standard ASTM D256 (¼″ notched) at 23° C. Some compositions comprising a polycarbonate resin and an ethylene-alkyl(meth)acrylate copolymer resin may also have a Heat Distortion Temperature of greater than or equal to about 120° C., and more preferably greater than or equal to about 127° C., when, when a specimen of the thermoplastic composition is tested in accordance with ASTM D648 under a 18.6 kgf load.

Other embodiments relate to a thermoplastic composition additionally comprising a rubber modified vinyl graft copolymer and a vinyl copolymer as herein described. Such compositions offer advantages over other compositions less one or more the components.

In some embodiments, a thermoplastic resin comprising a polycarbonate resin, an ethylene-alkyl(meth)acrylate copolymer resin, a rubber modified vinyl graft copolymer resin, and a vinyl copolymer has an impact strength of greater than or equal to about 52 kgf·cm/cm, when a specimen of the thermoplastic composition is tested according to the standard ASTM D256 (¼″ notched) at 23° C. In some embodiments, a thermoplastic resin comprising a polycarbonate resin, an ethylene-alkyl(meth)acrylate copolymer resin, a rubber modified vinyl graft copolymer resin, and a vinyl copolymer has an impact strength of greater than or equal to about 55 kgf·cm/cm, when a specimen of the thermoplastic composition is tested according to the standard ASTM D256 (¼″ notched) at 23° C. In some embodiments, a thermoplastic resin comprising a polycarbonate resin, an ethylene-alkyl(meth)acrylate copolymer resin, a rubber modified vinyl graft copolymer resin, and a vinyl copolymer has an impact strength of greater than or equal to about 61 kgf·cm/cm, when a specimen of the thermoplastic composition is tested according to the standard ASTM D256 (¼″ notched) at 23° C.

In some embodiments, a thermoplastic resin comprising a polycarbonate resin, an ethylene-alkyl(meth)acrylate copolymer resin, a rubber modified vinyl graft copolymer resin, and a vinyl copolymer has a melt flow index of greater than or equal to about 5 g/10 min, when a specimen of the thermoplastic composition is tested according to the standard ASTM D1238 at 250° C. and a 2.16 kg load. In some embodiments, a thermoplastic resin comprising a polycarbonate resin, an ethylene-alkyl(meth)acrylate copolymer resin, a rubber modified vinyl graft copolymer resin, and a vinyl copolymer has a melt flow index of greater than or equal to about 8 g/10 min, when a specimen of the thermoplastic composition is tested according to the standard ASTM D1238 at 250° C. and a 2.16 kg load. In some embodiments, a thermoplastic resin comprising a polycarbonate resin, an ethylene-alkyl(meth)acrylate copolymer resin, a rubber modified vinyl graft copolymer resin, and a vinyl copolymer has a melt flow index of greater than or equal to about 10.6 g/10 min, when a specimen of the thermoplastic composition is tested according to the standard ASTM D1238 at 250° C. and a 2.16 kg load.

In some embodiments, a thermoplastic resin comprising a polycarbonate resin, an ethylene-alkyl(meth)acrylate copolymer resin, a rubber modified vinyl graft copolymer resin, and a vinyl copolymer has a Heat Distortion Temperature of greater than or equal to about 112° C., and more preferably greater than or equal to about 117° C., when, when a specimen of the thermoplastic composition is tested in accordance with ASTM D648 under a 18.6 kgf load.

In certain embodiments, the thermoplastic compositions have one or more of enhanced impact strength, flowability, and heat distortion temperatures as described above.

Shaped Articles

A shaped article can be made using the thermoplastic composition according to the foregoing embodiments. In some embodiments, this article is molded into various shapes. An extrusion molding machine such as a vented extruder may be used. The thermoplastic composition of embodiments may be molded into various moldings using, for example, a melt-molding device. In embodiments, the thermoplastic composition material is formed into a pellet, which then may be molded into various shapes using, for example, injection molding, injection compression molding, extrusion molding, blow molding, pressing, vacuum forming or foaming. In one embodiment, the thermoplastic composition can be made into a pellet using melt-kneading, and the resulting pellets are molded into moldings through injection molding or injection compression molding.

In some embodiments, the thermoplastic composition can be applied to portable mobile communications devices, precision electrical parts and devices, precision automobile parts and other various articles which require excellent fatigue strength as well as mechanical strength such as impact strength.

As noted, in one embodiment, the thermoplastic composition is formed into pellets. In other embodiments, the thermoplastic composition is formed into structural parts of various consumer products, including electronic devices and appliances. In some embodiments, the thermoplastic composition may be molded into a housing or body of electronic or non-electronic devices. Examples of electrical devices, in which a molded article made of the blend of the thermoplastic composition according to embodiments of the invention are used, include car instrument panel (I/P) core, printers, computers, word processors, keyboards, personal digital assistants (PDA), telephones, mobile phones, cameras, facsimile machines, copy machines, electronic cash registers (ECR), desk-top electronic calculators, PDAs, cards, stationery holders, washing machines, refrigerators, vacuum cleaners, microwave ovens, lighting equipment, irons, TV, VTR, DVD players, video cameras, radio cassette recorders, tape recorders, mini disc players, CD players, speakers, liquid crystal displays, MP3 players, and electric or electronic parts and telecommunication equipment, such as connectors, relays, condensers, switches, printed circuit boards materials, coil bobbins, semiconductor sealing materials, electric wires, cables, transformers, deflecting yokes, distribution boards, clocks, watches, and the like.

Another embodiment provides an electronic device which includes a housing or a part, which is made of a thermoplastic composition as herein described. Some embodiments provide a method of making an electronic device, comprising providing an electrical circuit, providing a housing comprising a portion, and enclosing at least part of the electrical circuit with the housing, wherein the portion comprises embodiments of the thermoplastic composition as herein described.

The invention is further described in terms of the following examples which are intended for the purpose of illustration and not to be construed as in any way limiting the scope of the present invention, which is defined by the claims. In the following examples, all parts and percentage are by weight unless otherwise indicated.

### EXAMPLES

In the following examples, the components used to prepare thermoplastic resin compositions of the Examples and Comparative Examples are as follows:
(A) Polycarbonate Resin
   (a1) Bisphenol-A based polycarbonate with a weight average molecular weight (Mw) of about 24,000 was used.
   (a2) Bisphenol-A based polycarbonate with a weight average molecular weight (Mw) of about 32,000 was used.
(B) Ethylene-Alkyl (Meth)Acrylate Copolymer
   (b1) Ethylene-alkyl (meth)acrylate copolymer with a melt index of 5.0 g/10 min at 19° C., 2.16 kgf was used.
   (b2) Elvaloy AC EMA-1330 (product name) available from Dupont company was used.
(C) Rubber Modified Vinyl-Grafted Copolymer

58 parts of butadiene rubber latex, 31 parts of styrene, 11 parts of acrylonitrile, and 150 parts of deionized water were mixed. To the mixture, 1.0 parts of potassium oleate, 0.4 parts of cumen hydroperoxide, and 0.3 parts of t-dodecyl mercaptane for chain transfer agent were added. The mixture was kept at 75° C. for 5 hours to obtain ABS latex. To the ABS latex, 1% sulfuric acid was added, coagulated and dried to obtain graft copolymer resin in powder form.
(D) Vinyl Copolymer

71 parts of styrene, 29 parts of acrylonitrile, 120 parts of deionized water and 0.17 parts of azobisisobutylonitrile (AIBN) were mixed. To the blend, 0.5 parts of tricalciumphosphate and 0.4 parts of t-dodecyl mercaptan for chain transfer agent were added. The resultant solution was suspension polymerized at 75° C. for 5 hours. The resultant was washed, dehydrated and dried to obtain styrene-acrylonitrile copolymer (SAN) in a powder state.
(E) Phosphoric Acid Ester Compound

Triphenylphosphate (TPP) was used in Comparative Example 4.
(F) MBS Based Impact Modifier

C223A (product name) available from Mitsubishi Rayon Company (Japan) was used in Comparative Example 3.

### Examples 1-6

The components as shown in Table 1, an antioxidant and a heat stabilizer were added in a conventional mixer and the mixture was extruded through a twin screw extruder with L/D=35 and Φ=45 mm to prepare a product in pellet form. The resin pellets were dried at 80° C. for more than 5 hours and molded into test specimens in a 10 oz. injection molding machine at 250° C.

### Comparative Examples 1-5

Comparative Example 1 was conducted in the same manner as in Example 4 except that the ethylene-alkyl (meth)acrylate copolymer was not used and the vinyl copolymer was used in an amount of 13 parts by weight.

Comparative Example 2 was conducted in the same manner as in Example 3 except that the ethylene-alkyl (meth)acrylate copolymer was not used and the vinyl copolymer was used in an amount of 8 parts by weight.

Comparative Example 3 was conducted in the same manner as in Example 3 except that the MBS based impact modifier was used instead of ethylene-alkyl (meth)acrylate copolymer.

Comparative Example 4 was conducted in the same manner as in Example 1 except that the ethylene-alkyl (meth)acrylate copolymer was not used and the phosphoric acid ester compound was used as a lubricant.

Comparative Example 5 was conducted in the same manner as in Example 6 except that the ethylene-alkyl (meth)acrylate copolymer was not used.

TABLE 1

| | | Examples | | | | | | Comparative Examples | | | | |
|---|---|---|---|---|---|---|---|---|---|---|---|---|
| | | 1 | 2 | 3 | 4 | 5 | 6 | 1 | 2 | 3 | 4 | 5 |
| (A) polycarbonate resin | (a₁) | — | — | 37 | — | — | 46 | — | 37 | 37 | — | 50 |
| | (a₂) | 77 | 77 | 40 | 77 | 77 | 46 | 77 | 40 | 40 | 77 | 50 |
| (B) ethylene-alkyl(meth) | (b₁) | 3 | — | — | 8 | — | 8 | — | — | — | — | — |
| acrylate copolymer | (b₂) | — | 3 | 3 | — | 8 | — | — | — | — | — | — |

| | | | | | | | | | | | |
|---|---|---|---|---|---|---|---|---|---|---|---|
| (C) rubber modified vinyl-grafted | 5 | 5 | 5 | 5 | 5 | — | 13 | 8 | 5 | 8 | — |
| copolymer | | | | | | | | | | | |
| (D) vinyl copolymer | 15 | 15 | 15 | 10 | 10 | — | 10 | 15 | 10 | 15 | — |
| (E) phosphoric acid ester compound | — | — | — | — | — | — | — | — | — | 8 | — |
| (F) MBS based impact modifier | — | — | — | — | — | — | — | — | 8 | — | — |

The specimens prepared in Examples 1-6 and Comparative Examples 1-5 were kept at the relative humidity of 50% at 23° C. for 48 hours. The physical properties of the test specimens were measured in accordance with ASTM regulations. Melt flow index was measured in accordance with in ASTM D1238 at 250° C. and a 2.16 kg load. The Izod impact strength was measured in accordance with ASTM D256 (¼″ notch, kgf·cm/cm) at 23° C. The heat distortion temperature (HDT) was measured in accordance with ASTM D648 under a 18.6 kgf load. The test results are shown in Table 2.

TABLE 2

| | Examples | | | | | | Comparative Examples | | | | |
|---|---|---|---|---|---|---|---|---|---|---|---|
| | 1 | 2 | 3 | 4 | 5 | 6 | 1 | 2 | 3 | 4 | 5 |
| melt flow index (250° C., 2.16 kg) | 6.4 | 6.2 | 8 | 10.7 | 10.6 | 5 | 2 | 3.7 | 2 | 7.1 | 1.5 |
| Impact strength (1/4″) | 52 | 53 | 52 | 61 | 61 | 38 | 48 | 40 | 59 | 25 | 10 |
| HDT (° C.) | 117 | 117 | 117 | 112 | 112 | 127 | 113 | 117 | 113 | 80 | 130 |

As shown in Table 2, the resin compositions of Examples 1-6 employing an ethylene-alkyl(meth)acrylate copolymer have high heat distortion temperatures, impact strengths and flowability compared to Comparative Examples 1-5, which do not employ an ethylene-alkyl(meth)acrylate copolymer resin.

The skilled artisan will recognize the interchangeability of various features from different embodiments. Similarly, the various features and steps discussed above, as well as other known equivalents for each such feature or step, can be mixed and matched by one of ordinary skill in this art to perform compositions or methods in accordance with principles described herein. Although the invention has been disclosed in the context of certain embodiments and examples, it will be understood by those skilled in the art that the invention extends beyond the specifically disclosed embodiments to other alternative embodiments and/or uses and obvious modifications and equivalents thereof. Accordingly, the invention is not intended to be limited by the specific disclosures of embodiments herein. Rather, the scope of the present invention is to be interpreted with reference to the claims that follow.

What is claimed is:

1. A polymer composition comprising:
a polycarbonate resin; and
an ethylene-alkyl (meth)acrylate copolymer resin.

2. The polymer composition of claim 1, wherein the polymer composition comprises about 45 to about 95 parts by weight of the polycarbonate resin and about 0.1 to about 50 parts by weight of the ethylene-alkyl (meth)acrylate copolymer resin.

3. The polymer composition of claim 1, wherein the ethylene-alkyl (meth)acrylate copolymer resin comprises a polymer represented by Formula (I): 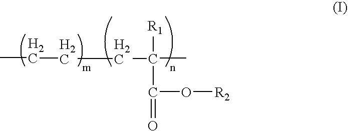
wherein R₁ is hydrogen or methyl,
wherein R₂ is hydrogen or C₁-C₁₂ alkyl,
and the ratio of m to n ranges from about 300:1 to about 10:90.

4. The polymer composition of claim 3, wherein the polymer represented by Formula (I) comprises one or more selected from the group consisting of a random polymer, a block polymer, and a multiblock polymer.

5. The polymer composition of claim 3, wherein R₂ is selected from the group consisting of hydrogen, methyl, ethyl, propyl, isopropyl, butyl, sec-butyl, t-butyl, isobutyl, isoamyl and t-amyl.

6. The polymer composition of claim 1, wherein the ethylene-alkyl (methyl) acrylate copolymer is a copolymer of ethylene and at least one monomer selected from the group consisting of acrylate, methyl acrylate, ethyl acrylate, propyl acrylate, isopropyl acrylate, butyl acrylate, sec-butyl acrylate, t-butyl acrylate, isobutyl acrylate, isoamyl acrylate, and t-amyl acrylate, methacrylate. methyl methacrylate, ethyl methacrylate, propyl methacrylate, isopropyl methacrylate, butylmethacrylate, sec-butyl methacrylate, t-butylmethacrylate, isobutyl methacrylate, isoamyl methacrylate, and t-amyl methacrylate.

7. The polymer composition of claim 1, wherein the polymer composition has impact strength of greater than or equal to about 35 kgf·cm/cm, when a specimen of the composition is tested according to the standard ASTM D256 (¼″ notched) at 23° C.

8. The polymer composition of claim 1, wherein the polymer composition has impact strength of greater than or equal to about 38 kgf·cm/cm, when a specimen of the composition is tested according to the standard ASTM D256 (¼″ notched) at 23° C.

9. The polymer composition of claim 13, wherein the polymer composition has a melt flow index of greater than or equal to about 5 g/10 min, when a specimen of the thermoplastic composition is tested according to the standard ASTM D1238 at 250° C. and a 2.16 kg load.

10. The polymer composition of claim 1, wherein the polymer composition has a Heat Distortion Temperature of greater than or equal to about 120° C., when a specimen of the thermoplastic composition is tested in accordance with ASTM D648 under a 18.6 kgf load.

11. The polymer composition of claim 1, wherein the polymer composition has a Heat Distortion Temperature of greater than or equal to about 127° C., when a specimen of the thermoplastic composition is tested in accordance with ASTM D648 under a 18.6 kgf load.

12. The polymer composition of claim 1 in the form of a molded article.

13. The polymer composition of claim 1, further comprising:
a rubber modified vinyl graft copolymer resin; and
a vinyl copolymer.

14. The polymer composition of claim 13, wherein the polymer composition comprises about 0 to about 50 parts by weight of the rubber modified vinyl graft copolymer resin and about 0 to about 50 parts by weight of the vinyl copolymer.

15. The polymer composition of claim 13, wherein the polymer composition has impact strength of greater than or equal to about 52 kgf·cm/cm, when a specimen of the composition is tested according to the standard ASTM D256 (¼- notched) at 23° C.

16. The polymer composition of claim 13, wherein the polymer composition has impact strength of greater than or equal to about 55 kgf·cm/cm, when a specimen of the composition is tested according to the standard ASTM D256 (¼- notched) at 23° C.

17. The polymer composition of claim 13, wherein the polymer composition has impact strength of greater than or equal to about 61 kgf·cm/cm, when a specimen of the composition is tested according to the standard ASTM D256 (¼- notched) at 23° C.

18. The polymer composition of claim 13, wherein the polymer composition has a Heat Distortion Temperature of greater than or equal to about 112° C., when a specimen of the thermoplastic composition is tested in accordance with ASTM D648 under a 18.6 kgf load.

19. The polymer composition of claim 13, wherein the polymer composition has a Heat Distortion Temperature of greater than or equal to about 117° C., when a specimen of the thermoplastic composition is tested in accordance with ASTM D648 under a 18.6 kgf load.

20. The polymer composition of claim 13, wherein the polymer composition has a melt flow index of greater than or equal to about 8 g/10 min, when a specimen of the thermoplastic composition is tested according to the standard ASTM D1238 at 250° C. and a 2.16 kg load.

21. The polymer composition of claim 13, wherein the polymer composition has a melt flow index of greater than or equal to about 10.6 g/10 min, when a specimen of the thermoplastic composition is tested according to the standard ASTM D1238 at 250° C. and a 2.16 kg load.

22. A method of making a plastic structure, the comprising:
providing the polymer composition of claim 1; and
molding the polymer composition into a shape.

23. A method of making a plastic structure, the comprising:
providing the polymer composition of claim 13; and
molding the polymer composition into a shape.

24. A method of making an electronic device, the method comprising:
providing an electronic circuit; and
providing a housing substantially enclosing the electronic circuit, the housing comprising a portion, which comprises the polymer composition of claim 1.

25. A method of making an electronic device, the method comprising:
providing an electronic circuit; and
providing a housing substantially enclosing the electronic circuit, the housing comprising a portion, which comprises the polymer composition of claim 13.

26. An electronic device comprising a housing, wherein the housing comprises a portion comprising the polymer composition of claim 1.

27. An electronic device comprising a housing, wherein the housing comprises a portion comprising the polymer composition of claim 13.
